(19) United States
(12) Patent Application Publication
(10) Pub. No.: US 2003/0085454 A1
(43) Pub. Date: May 8, 2003

(54) Chip card and production process

(76) Inventors: Ulrich Reutner, Nussloch (DE); Karl-Heinz Wendisch, Nussloch (DE)

Correspondence Address: Joseph W. Berenato, III, Liniak, Berenato & White, LLC, Suite 240, 6550 Rock Spring Drive, Bethesda, MD, 20817, US

(21) Appl. No.: 10/270,179

(22) Filed: Oct. 15, 2002

(30) Foreign Application Priority Data
Oct. 12, 2001 (DE) 101 50 205.9

(51) Int. Cl. H01L 23/02

(52) U.S. Cl. 257/679

(57) ABSTRACT

A chip card with a multitude of superimposed card layers bonded together by heat and pressure, wherein an interior supporting layer on an upper side of the same has an antenna coil with a multitude of printed conductors and coil pads arranged at the end thereof, on the one hand, and a recess for accommodating a chip module, on the other hand, [so] that the coil pads are arranged in a contacting area running on both sides of the printed conductor section formed by the printed conductors running side by side, wherein the recess is arranged in the printed conductor section in such a way that the chip module can be inserted inside the recesses by disposing the chip connectors thereof directly on the coil pad of the antenna coil.

The invention concerns a chip card with a multitude of superimposed card layers bonded together by heat and pressure, wherein an interior supporting layer has on the upper side thereof an antenna coil with a multitude of printed conductors and coil pads arranged at the ends thereof, on the one hand, and a recess for accommodating a chip module, on the other hand, [so] that the coil pads are arranged in a contact area on both sides of a printed conductor section formed by the printed conductors running side by side.

The invention also concerns a process for producing a supporting layer in which an antenna coil as well as also a chip module is integrated.

A chip card with a supporting layer which carries an antenna coil, wherein to effect a contact of the coil pads of the antenna coil with fixedly arranged chip connectors of the chip module are used so-called electrically conducting lead frames, is known from DE 196 40 260 A1. For this purpose, the coil pads have corresponding breakthroughs, through which the ends of the lead frames can be guided, deflected, and subsequently mechanically and electrically connected flatly against the coil pad by forming weld points.

The object of the invention is to provide a chip card and a process for producing a supporting layer in such a way that the contact between the coil pads of the antenna coil, on the one hand, and the chip connectors of the chip module, on the other hand, is simplified.

To attain this object, the chip card in accordance with the invention is characterized in that the recess is arranged in the printed conductor section, while the printed conductors cover over the recess containing the chip module by direct application on the chip module.

To attain the object a production process in accordance with the invention according to claims 9 to 11 is proposed.

The particular advantage of the chip card or the supporting layer in accordance with the invention consists in that a direct and immediate contacting of the chip connectors of the chip module with the coil pads of the antenna coil is made possible. The introduction of additional components for contacting or the introduction of contacting bridges for bridging a coil pad from one side of the printed conductor section to the opposite-lying side of the printed conductor section, in which the other coil pad is arranged, is not required. It is a basic idea of the invention to form the recess directly in the printed conductor section, so that a direct contact of the chip module on the printed conductors of the printed conductor section as well as a direct contact of the chip connectors on the coil pad is made possible.

The printed conductors or coil pads are advantageously uncovered on the supporting layer immediately after being placed thereon, so that a direct contacting with the chip module is made possible without additional measures. The printed conductors, which span the recess, are supported directly on one side of the chip module, so that their position is stabilized. The printed conductors extend at a constant distance with respect to each other over the recess, so that, taking into consideration the surface of the recess covered by the coil pads, the covered and therefore unexposed area of the recess is more than 50% of its total surface.

According to a preferred embodiment of the invention, the distance between the chip connectors is equal to the distance between the coil pads, so that the chip connectors arranged on the upper side of the chip module facing toward one of the printed conductors make direct contact on the coil pads in the contacting position.

According to another embodiment of the invention, the chip module is configured as an embedded body, in particular an encapsulated surface mounted device component in which the chip is arranged. Proven production techniques known from the production of semiconductors can be advantageously applied herein.

According to a further embodiment of the invention, the chip module in the recess is aligned flush with respect to the upper side and/or the lower side of the supporting layer. When the alignment is completely flush, a carrier film with approximately planar sides is produced therefore. Merely the printed conductors and the coil pads are at a distance from an upper side of the supporting layer or of the chip module.

According to a further embodiment of the invention, the coil connectors are electrically conducting and mechanically connected to the coil pads by means of a conducting adhesive. In this way there is produced a carrier film, which carries not only the antenna coil, but also the chip module. In this way there is advantageously obtained an easily produced semi-finished product, which makes possible a problem-free further processing to a chip card.

The processes in accordance with the invention make possible in a simple way the production of a supporting layer for an antenna coil as well as a chip module.

An exemplary embodiment of the invention is described in more detail in the following in view of the drawings, wherein:

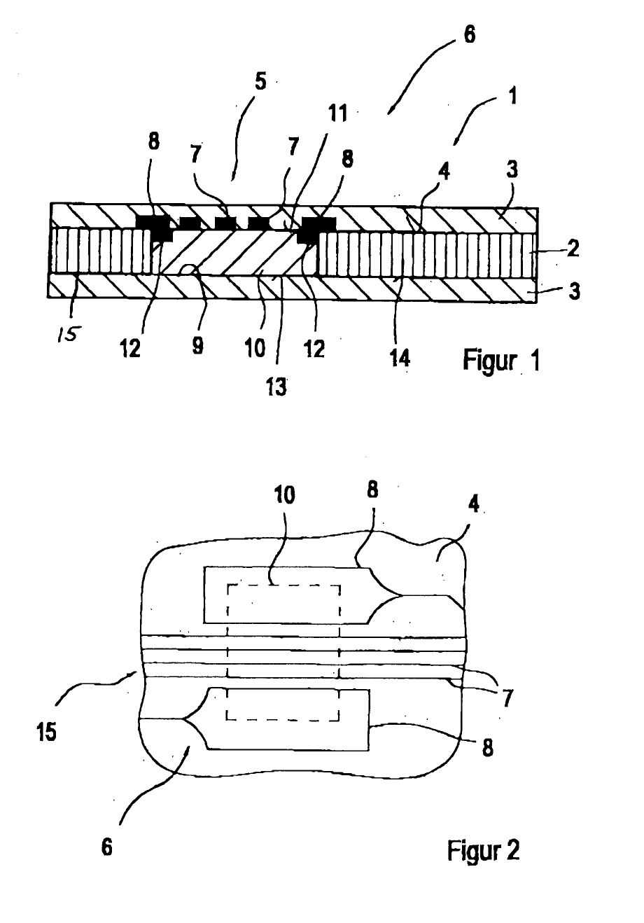

FIG. 1 shows a partial section through a chip card in a contacting area, and

FIG. 2 shows a partial plan view of a supporting layer with an antenna coil and a chip module in the contacting area.

A chip card 1 with a three-layer arrangement consists essentially of an interior supporting layer 2 (core layer) and two cover layers 3 attaching to both sides of the supporting layer 2. The cover layers 3 and the supporting layer 2 are fixedly bonded to each other in a lamination process by applying heat and pressure.

The supporting layer 2 has on an upper side 4 an antenna coil 5 provided with several windings. In a contacting area 6 of the antenna coil 5, the ends of the essentially circularly or polygonally arranged printed conductors 7, which form the antenna coil 5, have widened coil pads 8. Between the coil pads 8 extend in the same plane a multitude of printed conductors 7; in the exemplary embodiment, these are four printed conductors. The coil pads 8 delimit in this way the widest printed conductor section of the antenna coil 5. Between the coil pads 8 extend all the windings of the antenna coil 5.

In the printed conductor section arranged in this manner between the coil pads 8, the supporting layer 2 has a recess 9 for accommodating a chip module 10. The shape of the recess 9 corresponds to the shape of the chip module 10. On the edge of an upper side 11 of the chip module 10 allocated to the printed conductors 7 are configured corresponding chip connectors 12, which are supported directly on the corresponding coil pad 8 in the assigned contacting position of the chip module 10. An electrically conducting and mechanical connection between the chip connectors 12, on the one hand, and the coil pads 8 can be effected by providing an electrically conducting adhesive.

The width of the recess 9 is configured in such a way that a partial area of the coil pad 8 is exposed below for contact with the chip connectors 12. Another partial area supported on the outside of the coil pad 8 is connected directly to the supporting layer 2.

In the exemplary embodiment, the upper side 11 of the chip module 10 as well as also a lower side 13 of the chip module 10 are aligned flush with the upper side 4 of the supporting layer 2 or a lower side 15 of the supporting layer 2. After inserting or contacting the chip module 10 in the recess 9, the supporting layer 2 acquires a flat configuration on both sides without significant elevations. In this way easy further processing to a chip card can take place. The elevation of the printed conductors 7 or the coil pads 8 in FIG. 2 is shown overdimensioned for reasons of clarity. Their thickness is comparatively small in comparison with the thickness of the supporting layer 2.

The chip module 10 is configured as an embedded body, in particular an encapsulated surface mounted device component, in which the chip is arranged. There is a conducting contact between the chip and the chip connectors 12.

The production of the supporting layer 2, which can be preferably an intermediate product, will be described in the following.

The supporting layer 2 can be configured as a carrier film consisting of polyester, polyvinyl chloride (PVC), polycarbonate (PC), polyethylene terephthalate (PET), polymethyl methacrylate (PMMA), PEN, or configured as a plastic reinforced with glass fibers.

According to a first embodiment of a production process, the recess 9 is formed in the contacting area 6 of the supporting layer 2. The chip module 10 is subsequently inserted into the recess 9 with a flush connection to both sides of the carrier film 2. In another step, the antenna coil 5 is transferred toward the upper side 4 of the supporting layer 2, while the coil pads 8 are positioned in correspondence with the chip connections 12. The printed conductors 7 arranged between the coil pads 8 are supported directly on the upper side 11 of the chip module 10. The electrical contact and mechanical connection between the carrier film 2 or the coil pad 8 and the chip connectors 12 takes place by utilizing an electrically conducting adhesive. In this way, the supporting layer is produced as a semi-finished product and can be further processed to produce a chip card 1 according to known processes.

According to a second production process, the antenna coil 5 is first mounted on the upper side 4 of the supporting layer 2 by forming coil pads 8. This can take place by means of a known etching procedure or by winding the antenna coil 5. The recess 9 is formed thereafter by milling from the lower side 14 of the supporting layer 2 and in particular until the coil pad 8 is released at least in part from the back. Afterward, the chip module 10 can be inserted from the lower side by disposing the chip connectors 12 directly on the coil pads 8. The contact between the chip connectors 12, on the one hand, and the coil pads 8, on the other hand, is effected via an electrically conducting adhesive. The supporting layer 2 is henceforth the support of the antenna coils 5 and the chip module for the antenna coil 5 and the chip module 10 and can be processed further to a chip card 1 in the manner described above

1. A chip card with a multitude of superimposed card layers bonded to each other via heat and pressure, wherein an interior supporting layer on an upper side thereof has an antenna coil with a multitude of printed conductors and coil pads arranged at the ends thereof, on the one hand, and a recess for accommodating a chip module, on the other hand, [so] that the coil pads are arranged in a contacting area on both sides of a printed conductor section formed by the printed conductors running side by side, characterized in that the recess (9) is arranged in the printed conductor section (15), wherein the printed conductors (7) cover over the recess (9) containing the chip module (10) by direct application on the chip module (10).

2. The chip card according to claim 1, characterized in that the printed conductors (7) are arranged uncovered on the chip module.

3. The chip card according to claim 1 or 2, characterized in that the printed conductors (7) are configured as printed conductors (7) installed or wound or etched on the supporting layer (2) in the printed conductor section (15) supported directly on the chip module (10).

4. The chip card according to one of the claims 1 to 3, characterized in that the chip connectors (12) of the chip module (10) are supported directly on the coil pads (8) of the antenna coil (5), while the chip connectors (12) are arranged on an upper side (4) of the supporting layer (2) facing the upper side (11) of the chip module (10) at a distance with respect to each other, which corresponds to the distance of the coil pads (8) with respect to each other.

5. The chip card according to one of the claims 1 to 4, characterized in that the chip module (10) is configured as an embedded body, in particular a surface mounted device component, whose upper side (11) and/or whose lower side (13) is aligned flush with the upper side (4) of the supporting layer (2) or the lower side (14) of the supporting layer (2).

6. The chip card according to one of the claims 1 to 5, characterized in that the chip connectors (12) are electrically conducting and mechanically connected by means of a conducting adhesive to the corresponding coil pads (8).

7. The chip card according to one of the claims 1 to 6, characterized in that the supporting layer (2) is produced from polyethylene or polycarbonate or PVC or PEN.

8. A use of a core layer according to one of the claims 1 to 5 as a carrier film for accommodating the antenna coil (5) and the chip module (10).

9. A process for producing a supporting layer according to one of the claims 1 to 7, wherein the chip module (10) is positioned in the recess (9) of the supporting layer (2) and the antenna coil (5) is then mounted on the upper side (4) of the supporting layer (2).

10. The process according to claim 9, characterized in that the antenna coil (5) is mounted by transferring the same onto the supporting layer (2).

11. The process for producing a supporting layer according to one of the claims 1 to 7, wherein first the antenna coil (5) is mounted on the upper side (4) of the supporting layer (2), subsequently the recess (9) is milled away from a lower side (14) of the supporting layer (2), and then the chip module (10) is inserted by placing the same on the printed conductor section inside the recess (9).

12. The process according to claim 11, characterized in that the antenna coil (5) is mounted by etching or as an wound antenna coil (5) on the supporting layer (2).
